(19) United States
(12) Patent Application Publication
(10) Pub. No.: US 2020/0112295 A1
(43) Pub. Date: Apr. 9, 2020

(54) RESONATOR AND RESONANT DEVICE

(71) Applicant: Murata Manufacturing Co., Ltd., Nagaokakyo-shi (JP)

(72) Inventors: Ryota Kawai, Nagaokakyo-shi (JP); Ville Kaajakari, Helsinki (FI)

(21) Appl. No.: 16/705,935

(22) Filed: Dec. 6, 2019

Related U.S. Application Data
(63) Continuation of application No. PCT/JP2018/007036, filed on Feb. 26, 2018.
(60) Provisional application No. 62/522,275, filed on Jun. 20, 2017.

(51) Int. Cl. H03H 3/007; H03H 9/05; H03H 9/10; H03H 9/24

(52) U.S. Cl. CPC H03H 3/0077; H03H 9/2457; H03H 9/1057; H03H 9/0595

(57) ABSTRACT

A manufacturing method is provided for a resonant device that includes a resonator having a vibrating portion that vibrates according to a voltage applied to an electrode of the resonator. The method includes forming an adjusting film made of molybdenum oxide in a displacement region having a greater displacement caused by vibrations when the voltage is applied than a displacement of another region in the vibrating portion. The method further includes adjusting a frequency of the resonator by removing at least part of the adjusting film with laser.

### CROSS REFERENCE TO RELATED APPLICATIONS

The present application is a continuation of PCT/JP2018/007036 filed Feb. 26, 2018, which claims priority to U.S. Provisional Patent Application No. 62/522,275, filed Jun. 20, 2017, the entire contents of each of which are incorporated herein by reference.

### TECHNICAL FIELD

The present invention relates to a resonator of which a vibrating arm vibrates in an out-of-plane bending vibration mode, and a method of manufacturing the same.

### BACKGROUND

Currently, resonant devices that uses a MEMS (micro electro mechanical systems) technology are used as, for example, a timing device. Such resonant devices are implemented on a printed circuit board to be incorporated into an electronic device, such as a smartphone. In general, the resonant device includes a lower substrate, an upper substrate that forms a cavity with the lower substrate, and a resonator disposed in the cavity between the lower substrate and the upper substrate.

In such a resonator, a technique for adjusting frequency by irradiating laser from above the lid after the resonator is sealed by a top lid and a bottom lid is known. For example, Patent Document 1 (identified below) describes a laser irradiating method that is able to irradiate laser to an object beyond a silicon material by transmitting laser through the silicon material while minimizing damage to the silicon material and components around the silicon material. Moreover, Patent Document 1 describes a frequency adjusting method for a piezoelectric resonator using the laser irradiating method. With the method described in Patent Document 1, the resonant frequency of a piezoelectric resonator is adjusted by irradiating pulse laser having a pulse width of 50 to 1000 fs to a silicon material region of a package of an electronic component to transmit the pulse laser therethrough and irradiating the transmitted laser to the piezoelectric resonator.

Patent Document 1: International Publication No. 2011/043357.

In the technical field in which a resonant device using a MEMS technology is used, a further easy, highly accurate frequency adjusting method is sought, and there is room for further improvement.

### SUMMARY OF THE INVENTION

Accordingly, it is an object of the exemplary embodiments of the present invention to provide a further easy, highly accurate frequency adjusting method.

Thus, a manufacturing method for a resonant device is disclosed herein that includes forming a resonator having a vibrating portion configured to vibrate according to a voltage applied to an electrode of the resonator. Moreover, the method includes forming a base film made of molybdenum in a region of the vibrating portion whose displacement caused by vibrations is greater than a displacement of another region in the vibrating portion, forming a plurality of spot-shaped adjusting films made of molybdenum oxide on the base film by oxidizing the molybdenum, and adjusting a frequency of the resonator by removing at least part of the plurality of spot-shaped adjusting films with laser.

### BRIEF DESCRIPTION OF DRAWINGS

FIG. 1 is a perspective view that schematically shows the appearance of a resonant device according to a first exemplary embodiment.

FIG. 2 is an exploded perspective view that schematically shows the structure of the resonant device according to the first exemplary embodiment.

FIG. 3 is a plan view of a resonator according to the first exemplary embodiment in a state where an upper substrate is removed.

FIG. 4 is a cross-sectional view taken along the line A-A′ in FIG. 3.

FIG. 5A is a view that shows a manufacturing process for the resonant device according to the first exemplary embodiment.

FIG. 5B is a view that shows the manufacturing process for the resonant device according to the first exemplary embodiment.

FIG. 5C is a view that shows the manufacturing process for the resonant device according to the first exemplary embodiment.

FIG. 5D is a view that shows the manufacturing process for the resonant device according to the first exemplary embodiment.

FIG. 5E is a view that shows the manufacturing process for the resonant device according to the first exemplary embodiment.

FIG. 5F is a view that shows the manufacturing process for the resonant device according to the first exemplary embodiment.

FIG. 5G is a view that shows the manufacturing process for the resonant device according to the first exemplary embodiment.

FIG. 5H is a view that shows the manufacturing process for the resonant device according to the first exemplary embodiment.

FIG. 5I is a view that shows the manufacturing process for the resonant device according to the first exemplary embodiment.

FIG. 5J is a view that shows the manufacturing process for the resonant device according to the first exemplary embodiment.

FIG. 5K is a view that shows the manufacturing process for the resonant device according to the first exemplary embodiment.

FIG. 5L is a schematic diagram that shows a state of an F adjusting step according to the first exemplary embodiment.

FIG. 6 corresponds to FIG. 3 and is a plan view of the resonator in the case where an adjusting film is formed on the entire surface of a base film.

FIG. 7 is a plan view of a resonator according to a second exemplary embodiment.

FIG. 8 is a cross-sectional view taken along the line C-C′ in FIG. 7.

FIG. 9 is a plan view of a resonator according to a third exemplary embodiment.

FIG. 10 is a cross-sectional view taken along the line D-D′ in FIG. 9.

FIG. 11 corresponds to FIG. 9 and is a diagram that shows the planar structure of a vibrating portion in the case where the vibrating portion vibrates in harmonic mode.

FIG. 12 is a plan view of a resonator according to a fourth exemplary embodiment.

FIG. 13A is a diagram that shows another mode of a manufacturing method for a resonant device according to an exemplary aspect.

FIG. 13B is a diagram that shows another mode of the manufacturing method for a resonant device according to an exemplary aspect.

FIG. 13C is a diagram that shows another mode of the manufacturing method for a resonant device according to an exemplary aspect.

FIG. 13D is a diagram that shows another mode of the manufacturing method for a resonant device according to an exemplary aspect.

FIG. 13E is a diagram that shows another mode of the manufacturing method for a resonant device according to an exemplary aspect.

FIG. 13F is a diagram that shows another mode of the manufacturing method for a resonant device according to an exemplary aspect.

FIG. 13G is a diagram that shows another mode of the manufacturing method for a resonant device according to an exemplary aspect.

FIG. 13H is a diagram that shows another mode of the manufacturing method for a resonant device according to an exemplary aspect.

FIG. 13I is a diagram that shows another mode of the manufacturing method for a resonant device according to an exemplary aspect.

FIG. 13J is a diagram that shows another mode of the manufacturing method for the resonant device according to an exemplary aspect.

### DETAILED DESCRIPTION OF EMBODIMENTS

### First Exemplary Embodiment

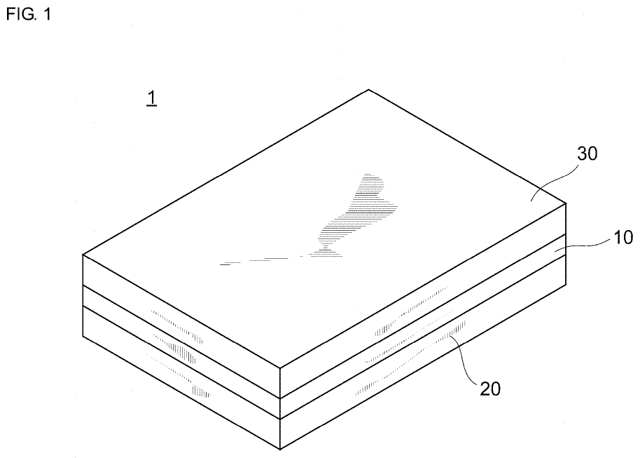

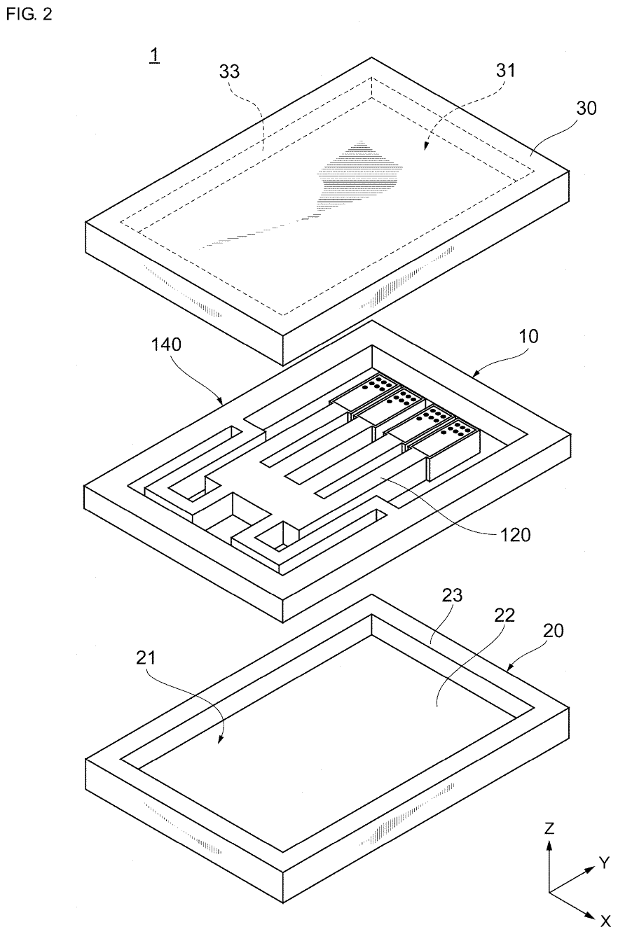

Hereinafter, a first exemplary embodiment will be described with reference to the attached drawings. FIG. 1 is a perspective view that schematically shows the appearance of a resonant device 1 according to the first exemplary embodiment. FIG. 2 is an exploded perspective view that schematically shows the structure of the resonant device 1 according to the first exemplary embodiment.

As shown, the resonant device 1 includes a resonator 10, and a top lid 30 and a bottom lid 20 provided to face each other with the resonator 10 interposed therebetween. In other words, the resonant device 1 is made up of the bottom lid 20, the resonator 10, and the top lid 30, stacked in this order.

The resonator 10 is bonded to the bottom lid 20 and the top lid 30. Thus, the resonator 10 is encapsulated, and a vibrating space for the resonator 10 is formed. In an exemplary aspect, the resonator 10, the bottom lid 20, and the top lid 30 each are made from an Si substrate. Moreover, the resonator 10, the bottom lid 20, and the top lid 30 are bonded to each other by bonding the Si substrates to each other. The resonator 10 and the bottom lid 20 may be made from an SOI substrate.

The resonator 10 is a MEMS resonator manufactured by using the MEMS technology. In the present embodiment, description will be made on the assumption that the resonator 10 is made from, for example, a silicon substrate. Hereinafter, the components of the resonant device 1 will be described in detail.

Top Lid 30

The top lid 30 expands in a planar shape along an XY-plane and has, for example, a flat rectangular parallelepiped recess 31 at its back surface. The recess 31 is surrounded by a side wall 33 and forms part of a vibrating space that is a space in which the resonator 10 vibrates.

Bottom Lid 20

The bottom lid 20 has a rectangular planar bottom plate 22 provided along the XY-plane and a side wall 23 extending in a Z-axis direction (that is, a direction in which the bottom lid 20 and the resonator 10 are stacked) from a peripheral portion of the bottom plate 22. The bottom lid 20 has a recess 21 at a surface facing the resonator 10. The recess 21 is formed by a surface of the bottom plate 22 and an inner surface of the side wall 23. The recess 21 is part of the vibrating space for the resonator 10. The vibrating space is hermetically sealed by the above-described top lid 30 and bottom lid 20 and is maintained in a vacuum state. The vibrating space may be filled with gas, such as inert gas.

Resonator 10

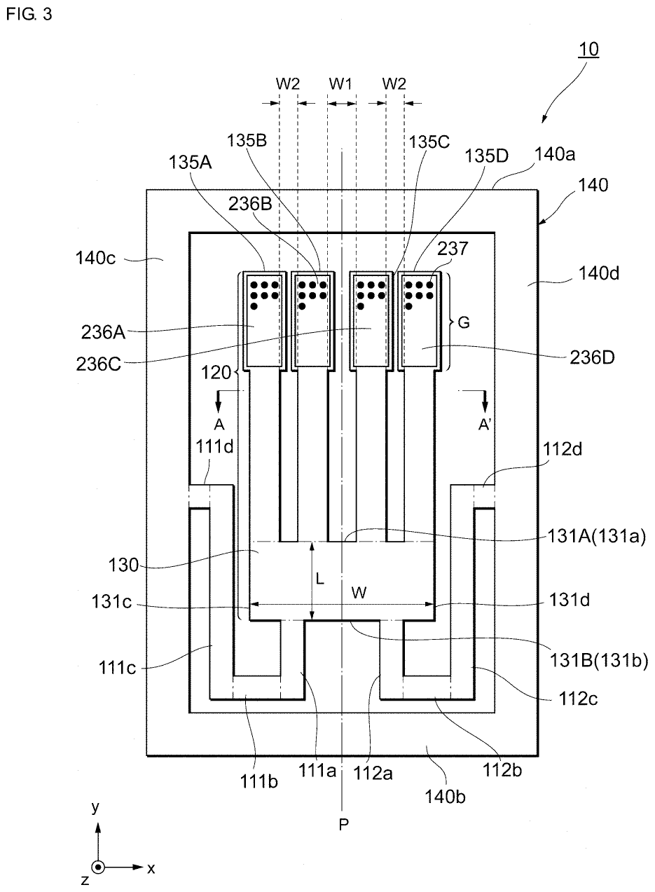

FIG. 3 is a plan view that schematically shows the structure of the resonator 10 according to the present embodiment. The components of the resonator 10 according to the present embodiment will be described with reference to FIG. 3. The resonator 10 includes a vibrating portion 120, a holding portion 140, holding arms 111, 112, and an adjusting film 237.

(a) Vibrating Portion 120

The vibrating portion 120 has a rectangular outline and expands along the XY-plane in the Cartesian coordinate system of FIG. 3. The vibrating portion 120 is provided on the inner side of the holding portion 140. A space is formed with a predetermined clearance between the vibrating portion 120 and the holding portion 140. In the example of FIG. 3, the vibrating portion 120 includes a base portion 130 and four vibrating arms 135A to 135D (also collectively referred to as vibrating arms 135). It should be appreciated that the number of the vibrating arms is not limited to four and is set to a selected number. In the present embodiment, each vibrating arm 135 and the base portion 130 are integrally formed.

Base Portion 130

As further shown, the base portion 130 has long sides 131a, 131b in an X-axis direction and short sides 131c, 131d in a Y-axis direction in plan view. The long side 131a is one of the sides of a surface 131A (hereinafter, also referred to as front end 131A) at a front end of the base portion 130. The long side 131b is one of the sides of a surface 131B (hereinafter, also referred to as rear end 131B) at a rear end of the base portion 130. In the base portion 130, the front end 131A and the rear end 131B are provided to face each other.

The base portion 130 is connected to the vibrating arms 135 (described later) at the front end 131A and connected to the holding arms 111, 112 (described later) at the rear end 131B. The base portion 130 has a substantially rectangular shape in plan view in the example of FIG. 3; however, it is noted that the base portion 130 is not limited thereto. Instead, the base portion 130 just needs to be formed substantially symmetrically with respect to an imaginary plane P that is defined along the perpendicular bisector of the long side 131a. The base portion 130 may have, for example, a trapezoidal shape in which the long side 131b is shorter than the long side 131a or a half-round shape having the long side 131a as a diameter. Each surface of the base portion 130 is not limited to a plane and may be a curved surface. The imaginary plane P is a plane including a central axis passing through the center of the vibrating portion 120 in a direction in which the vibrating arms 135 are arranged.

In the base portion 130, a base portion length L (in FIG. 3, the length of each of the short sides 131c, 131d) that is the longest distance between the front end 131A and the rear end 131B in a direction from the front end 131A toward the rear end 131B is approximately 35 μm. A base portion width W (in FIG. 3, the length of each of the long sides 131a, 131b) that is the longest distance between the side ends of the base portion 130 in a width direction perpendicular to the direction of the base portion length is approximately 280 μm.

Vibrating Arms 135

The vibrating arms 135 extend in the Y-axis direction and each have the same size. The vibrating arms 135 each are provided parallel to the Y-axis direction between the base portion 130 and the holding portion 140. One end of each vibrating arm 135 is connected to the front end 131A of the base portion 130 to serve as a fixed end, and the other end of each vibrating arm 135 serves as a free end. The vibrating arms 135 are arranged in the X-axis direction at predetermined intervals. The vibrating arms 135 each have, for example, approximately 50 μm in width in the X-axis direction and approximately 465 μm in length in the Y-axis direction.

In an exemplary aspect, the vibrating arms 135 each have a weight portion G at the free end. As shown, the weight portion G is wider in width in the X-axis direction than the other portion of the vibrating arm 135. The weight portion G is, for example, approximately 70 μm in width in the X-axis direction. The weight portion G is integrally formed in the same process with the vibrating arm 135. With the weight portion G, the weight of the vibrating arm 135 per unit length on the free end side is greater than that on the fixed end side. Therefore, since the vibrating arms 135 each have the weight portion G at the free end side, the amplitude of vibrations in an up-down direction in each vibrating arm can be increased.

In the vibrating portion 120 of the present embodiment, in the X-axis direction, the two vibrating arms 135A, 135D are disposed on the outer side, and the two vibrating arms 135B, 135C are disposed on the inner side. A clearance W1 between the vibrating arms 135B, 135C in the X-axis direction is set to preferably be greater than a clearance W2 between the outer vibrating arm 135A (135D) and the inner vibrating arm 135B (135C) adjacent to the outer vibrating arm 135A (135D) in the X-axis direction. The clearance W1 is, for example, approximately 30μ. The clearance W2 is, for example, approximately 25 μm. When the clearance W2 is set to less than the clearance W1, vibration characteristics are improved. However, when the resonant device 1 is miniaturized, the clearance W1 may be set to less than the clearance W2 or may be equal to the clearance W2.

Additional Exemplary Features

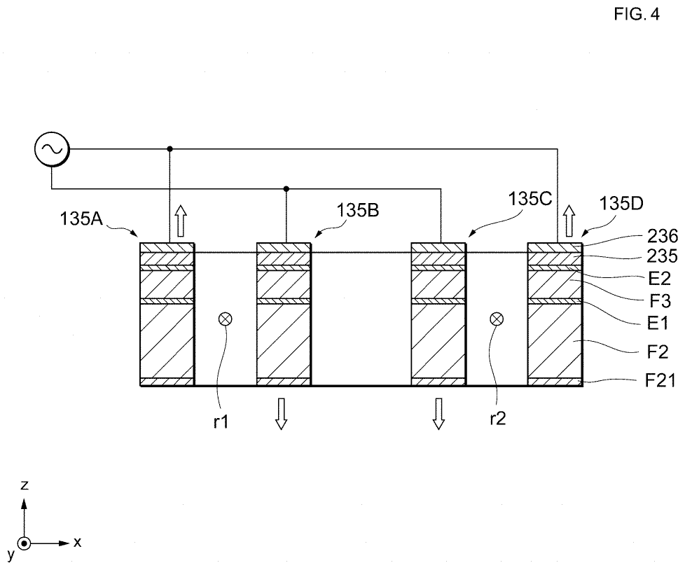

A protective film 235 (see FIG. 4) is formed on the surface (surface facing the top lid 30) of the vibrating portion 120 so as to cover the entire surface. In addition, base films 236A to 236D (hereinafter, the base films 236A to 236D are also collectively referred to as base films 236) are respectively formed partially on the surface of the protective film 235 in the vibrating arms 135A to 135D. The resonant frequency of the vibrating portion 120 can be adjusted with the protective film 235 and the base films 236. Although the protective film 235 does not necessarily cover the entire surface of the vibrating portion 120, it is desirable that the entire surface of the vibrating portion 120 be covered in terms of protecting a base electrode film (for example, a metal layer E2 in FIG. 4) and a base piezoelectric film (for example, a piezoelectric thin film F3 in FIG. 4) in frequency adjustment from damage.

The base films 236 each are formed on the protective film 235 in at least part of a region whose displacement caused by vibrations is greater than other regions on the vibrating portion 120 such that the surface is exposed. Specifically, each base film 236 is formed at the distal end of an associated one of the vibrating arms 135, that is, the weight portion G. On the other hand, the surface of the protective film 235 is exposed in the other region on the vibrating arms 135. In this embodiment, the base film 236 is formed up to the distal end of the vibrating arm 135 in the weight portion G, and the protective film 235 is not exposed at all at its distal end portion. However, the base film 236 may be not formed at the distal end portion of the vibrating arm 135 such that the protective film 235 is partially exposed.

(b) Holding Portion 140

The holding portion 140 (i.e., a frame) is formed in a rectangular frame shape along the XY-plane. The holding portion 140 is provided so as to surround the vibrating portion 120 along the XY-plane in plan view. It is noted that the holding portion 140 just needs to be provided at least partially around the vibrating portion 120 and is not limited to a frame shape. For example, the holding portion 140 just needs to be provided around the vibrating portion 120 to such an extent that the holding portion 140 holds the vibrating portion 120 and can be bonded to the top lid 30 and the bottom lid 20.

In the present embodiment, the holding portion 140 is made up of integrally formed square columnar frame elements 140a to 140d. As shown in FIG. 3, the frame element 140a faces the free ends of the vibrating arms 135, and the longitudinal direction of the frame element 140a is provided parallel to the X-axis. The frame element 140b faces the rear end 131B of the base portion 130, and the longitudinal direction of the frame element 140b is provided parallel to the X-axis. The frame element 140c faces the side end (short side 131c) of the base portion 130 and the vibrating arm 135A, the longitudinal direction of the frame element 140c is provided parallel to the Y-axis, and both ends of the frame element 140c are respectively connected to one ends of the frame elements 140a, 140b. The frame element 140d faces the side end (short side 131d) of the base portion 130 and the vibrating arm 135D, the longitudinal direction of the frame element 140d is provided parallel to the Y-axis, and both ends of the frame element 140d are respectively connected to the other ends of the frame elements 140a, 140b.

In the present embodiment, description will be made on the assumption that the holding portion 140 is covered with the protective film 235; however, it is noted that the exemplary configuration is not limited thereto. The protective film 235 need not be formed on the surface of the holding portion 140.

(c) Holding Arms 111, 112

The holding arm 111 and the holding arm 112 are provided on the inner side of the holding portion 140, and connect the rear end 131B of the base portion 130 to the frame elements 140c, 140d. As shown in FIG. 3, the holding arm 111 and the holding arm 112 are formed substantially symmetrically with respect to the imaginary plane P defined parallel to the YZ-plane along a center line of the base portion 130 in the X-axis direction.

The holding arm 111 is formed of arms 111a, 111b, 111c, 111d. One end of the holding arm 111 is connected to the rear end 131B of the base portion 130, and the holding arm 111 extends from there toward the frame element 140b. The holding arm 111 bends in a direction toward the frame element 140c (that is, the X-axis direction), further bends in a direction toward the frame element 140a (that is, the Y-axis direction), bends in a direction toward the frame element 140c (that is, the X-axis direction) again, and then the other end is connected to the frame element 140c.

The arm 111a is provided between the base portion 130 and the frame element 140b such that the arm 111a faces the frame element 140c and the longitudinal direction of the arm 111a is parallel to the Y-axis. One end of the arm 111a is connected to the base portion 130 at the rear end 131B, and the arm 111a extends from there substantially perpendicularly to the rear end 131B, that is, the arm 111a extends in the Y-axis direction. It is desirable that an axis passing through the center of the arm 111a in the X-axis direction be provided on the inner side with respect to the center line of the vibrating arm 135A. In the example of FIG. 3, the arm 111a is provided between the vibrating arm 135A and the vibrating arm 135B. The other end of the arm 111a is connected to one end of the arm 111b at its side surface. The arm 111a is approximately 20 μm in width defined in the X-axis direction and 40 μm in length defined in the Y-axis direction.

The arm 111b is provided between the base portion 130 and the frame element 140b such that the arm 111b faces the frame element 140b and the longitudinal direction of the arm 111b is parallel to the X-axis direction. One end of the arm 111b is connected to the other end of the arm 111a, that is, the side surface facing the frame element 140c, and the arm 111b extends from there substantially perpendicularly to the arm 111a, that is, the arm 111b extends in the X-axis direction. The other end of the arm 111b is connected to one end of the arm 111c, that is, a side surface facing the vibrating portion 120. The arm 111b is, for example, approximately 20 μm in width defined in the Y-axis direction and approximately 75 μm in length defined in the X-axis direction.

The arm 111c is provided between the base portion 130 and the frame element 140c such that the arm 111c faces the frame element 140c and the longitudinal direction of the arm 111c is parallel to the Y-axis direction. One end of the arm 111c is connected to the other end of the arm 111b at its side surface, and the other end of the arm 111c is connected to one end of the arm 111d, that is, a side surface on a frame element 140c side. The arm 111c is, for example, approximately 20 μm in width defined in the X-axis direction and approximately 140 μm in length defined in the Y-axis direction.

The arm 111d is provided between the base portion 130 and the frame element 140c such that the arm 111d faces the frame element 140a and the longitudinal direction of the arm 111d is parallel to the X-axis direction. One end of the arm 111d is connected to the other end of the arm 111c, that is, the side surface facing the frame element 140c. The other end of the arm 111d is connected to the frame element 140c at a position facing near a connection portion of the vibrating arm 135A with the base portion 130, and the arm 111d extends from there substantially perpendicularly to the frame element 140c, that is, the arm 111d extends in the X-axis direction. The arm 111d is, for example, approximately 20 μm in width defined in the Y-axis direction and approximately 10 μm in length defined in the X-axis direction.

In this way, the holding arm 111 is connected to the base portion 130 at the arm 111a, bends at the connection portion between the arm 111a and the arm 111b, the connection portion between the arms 111b, 111c, and the connection portion between the arms 111c, 111d, and is then connected to the holding portion 140.

The holding arm 112 is formed of arms 112a, 112b, 112c, 112d and in a similar configuration as holding arm 111. One end of the holding arm 112 is connected to the rear end 131B of the base portion 130, and the holding arm 112 extends from there toward the frame element 140b. The holding arm 112 bends in a direction toward the frame element 140d (that is, the X-axis direction), further bends in a direction toward the frame element 140a (that is, the Y-axis direction), bends in a direction toward the frame element 140d (that is, the X-axis direction) again, and then the other end is connected to the frame element 140d. The configurations of the arms 112a, 112b, 112c, 112d are respectively symmetrical to the configurations of the arms 111a, 111b, 111c, 111d, so the detailed description is omitted.

It should be appreciated that the holding arms 111, 112 are not limited to a shape bent at right angles at the connection portions of each arm and may have a curved shape. The number of times the holding arms 111, 112 bend is not limited to the above-described times. For example, the holding arms 111, 112 bend once and connect with the rear end 131B of the base portion 130 and the associated frame elements 140c, 140d, bend twice and connect with the rear end 131B of the base portion 130 and the frame element 140a, or connect with the rear end 131B of the base portion 130 and the frame element 140b without bending once. The connection portions of the holding arms 111, 112 in the base portion 130 are not limited to the rear end 131B. The holding arms 111, 112 may be connected to side surfaces connecting the front end 131A and the rear end 131B.

(d) Adjusting Films 237

According to the exemplary embodiment, a plurality of adjusting films 237 is formed in a dotted configuration on the base films 236. The plurality of adjusting films 237 each is a film made of spot-shaped molybdenum oxide formed at the distal end of each vibrating arm 135 for frequency adjustment. Part of the plurality of adjusting films 237 on each base film 236 is removed with laser (for example, laser having a wave length that transmits through a substrate) in an F adjusting step (described later). FIG. 3 shows a state after part of the adjusting films 237 is removed. In the example of FIG. 3, the adjusting films 237 formed at the same positions remain in any of the vibrating arm 135A to vibrating arm 135D; however, the configuration is not limited thereto. For example, the adjusting films 237 formed at different positions may remain in each vibrating arm 135. The diameter of the single adjusting film 237 is desirably less than the spot diameter of laser and is specifically greater than or equal to approximately 0.1 μm and less than or equal to approximately 20 μm.

Multilayer Structure

A multilayer structure of the resonator 10 will be described with reference to FIG. 4. FIG. 4 is a schematic view that shows the cross-sectional view taken along the line A-A′ in FIG. 3 and that schematically shows the electrical mode of connection of the resonator 10.

In the resonator 10, the holding portion 140, the base portion 130, the vibrating arms 135, and the holding arms 111, 112 are integrally formed in the same process. In the resonator 10, first, a metal layer E1 is laminated on an Si (silicon) substrate F2. The piezoelectric thin film F3 is laminated on the metal layer E1 so as to cover the metal layer E1. The metal layer E2 is further laminated on the surface of the piezoelectric thin film F3. The protective film 235 is laminated on the metal layer E2 so as to cover the metal layer E2. In the vibrating portion 120, the base films 236 are further laminated on the protective film 235, and the plurality of adjusting films 237 is further formed on the surfaces of the base films 236. When a degenerate silicon substrate having a low resistance is used, the Si substrate F2 also serves as the metal layer E1, so the metal layer E1 can be omitted.

According to the exemplary embodiment, the Si substrate F2 is made from, for example, a degenerate n-type Si semiconductor having a thickness of approximately 6 μm, and may contain P (phosphorus), As (arsenic), Sb (antimony), or the like, as an n-type dopant. The resistance value of the degenerate Si that is used for the Si substrate F2 is, for example, lower than 1.6 mΩ·cm and, more preferably, lower than or equal to 1.2 mΩ·cm. A silicon oxide (for example, SiO₂) layer (temperature characteristics correction layer) F21 is formed on the bottom surface of the Si substrate F2. Thus, temperature characteristics can be improved.

In the present embodiment, the silicon oxide layer (temperature characteristics correction layer) F21 is a layer having a function of reducing the temperature coefficient (that is, the rate of change per temperature) of frequency at least near room temperature in the vibrating portion when the temperature correction layer is formed on the Si substrate F2 as compared to when the silicon oxide layer F21 is not formed on the Si substrate F2. When the vibrating portion 120 has the silicon oxide layer F21, for example, a change, with temperature, in the resonant frequency of a multilayer structure made up of the Si substrate F2, the metal layers E1, E2, the piezoelectric thin film F3, and the silicon oxide layer (temperature correction layer) F21 is reduced.

In the resonator 10, the silicon oxide layer F21 is desirably formed with a uniform thickness. For purposes of this disclosure, it is noted that a uniform thickness means that variations in the thickness of the silicon oxide layer F21 fall within ±20% from an average value of the thickness.

The silicon oxide layer F21 may be formed on the top surface of the Si substrate F2 or may be formed on both the top surface and bottom surface of the Si substrate F2. In the holding portion 140, the silicon oxide layer F21 need not be formed on the bottom surface of the Si substrate F2.

The metal layers E2, E1 are formed from Mo (molybdenum), aluminum (Al), or another material, having a thickness of, for example, approximately 0.1 μm to approximately 0.2 μm. The metal layers E2, E1 are formed in a desired shape by etching, or another method. The metal layer E1 is formed to function as a lower electrode in, for example, the vibrating portion 120. In the holding arms 111, 112 or the holding portion 140, the metal layer E1 may be formed to function as a wire for connecting the lower electrode to an earth provided outside the resonator 10.

On the other hand, the metal layer E2 is formed to function as an upper electrode in the vibrating portion 120. In the holding arms 111, 112 or the holding portion 140, the metal layer E2 is formed to function as a wire for connecting the upper electrode to a circuit provided outside the resonator 10.

In connecting the alternating-current power supply and the earth to the lower wire or the upper wire, an electrode (i.e., an example of an outer electrode) may be formed on the outer surface of the top lid 30 to connect the circuit to the lower wire or the upper wire or a via may be formed in the top lid 30 and a wire may be formed by filling an electrically conductive material inside the via to connect the alternating-current power supply to the lower wire or the upper wire.

The piezoelectric thin film F3 is a thin film of a piezoelectric body that converts an applied voltage to vibrations and may contain, for example, a nitride, such as AlN (aluminum nitride), or an oxide as a main ingredient. Specifically, the piezoelectric thin film F3 may be made of ScAlN (scandium aluminum nitride). ScAlN is a substance in which part of aluminum in aluminum nitride is replaced with scandium. The piezoelectric thin film F3 has a thickness of, for example, 1 μm and may have a thickness of approximately 0.2 μm to approximately 2 μm.

The piezoelectric thin film F3 extends or contracts in an in-plane direction of the XY-plane, that is, Y-axis direction, in response to an electric field that is applied to the piezoelectric thin film F3 by the metal layers E2, E1. With this extension or contraction of the piezoelectric thin film F3, the vibrating arms 135 displace their free ends toward the inner surfaces of the bottom lid 20 and top lid 30 and vibrate in an out-of-plane bending vibration mode.

The protective film 235 is a layer of an electrically insulating body and is made of a material of which the rate of reduction in mass resulting from etching is lower than that of the base films 236. For example, the protective film 235 is made from a nitride film of AlN, SiN, or the like, or an oxide film of Ta₂O₅ (tantalum pentoxide), SiO₂, or the like. It should be appreciated that the rate of reduction in mass is expressed by the product of an etching rate (thickness that is removed per unit time) and a density. The thickness of the protective film 235 is less than or equal to half of the thickness of the piezoelectric thin film F3 and is, for example, approximately 0.2 μm in the present embodiment.

The base films 236 each are a layer of an electrically conductive body and made of a material of which the rate of reduction in mass resulting from etching is higher than that of the protective film 235. According to the exemplary aspect, the base films 236 are made of molybdenum (Mo).

As long as the relationship in the rate of reduction in mass between the protective film 235 and each base film 236 is as described above, the magnitude relation in etching rate is freely selected.

The base films 236 are formed by once forming a film over substantially the entire surface of the vibrating portion 120 and then forming the film into only predetermined regions by applying treatment, such as etching.

According to the exemplary embodiment, the adjusting films 237 are molybdenum oxide films having a predetermined shape, dotted on each base film 236, by oxidizing the base film 236. Moreover, there are many types of molybdenum oxides. For example, a molybdenum oxide is generally MoO₃ (molybdenum trioxide). Alternatively, a molybdenum oxide may be MoO₂ (molybdenum dioxide) or nonstoichiometric molybdenum oxides other than MoO₂. In addition, the thickness of each adjusting film 237 is, for example, approximately 0.1 μm to approximately 5 μm.

Function of Resonator

The function of the resonator 10 will be described with reference to FIG. 4. In the present embodiment, the phase of electric field that is applied to the outer vibrating arms 135A, 135D and the phase of electric field that is applied to the inner vibrating arms 135B, 135C are set to opposite phases from each other. Thus, the outer vibrating arms 135A, 135D and the inner vibrating arms 135B, 135C are displaced in opposite directions from each other. For example, when the outer vibrating arms 135A, 135D displace their free ends toward the inner surface of the top lid 30, the inner vibrating arms 135B, 135C displace their free ends toward the inner surface of the bottom lid 20.

Thus, in the resonator 10 according to the present embodiment, during vibrations in opposite phases, the vibrating arm 135A and the vibrating arm 135B vibrate in opposite directions in the up-down direction around a central axis r1 extending parallel to the Y-axis between the vibrating arm 135A and the vibrating arm 135B shown in FIG. 4. The vibrating arm 135C and the vibrating arm 135D vibrate in opposite directions in the up-down direction around a central axis r2 extending parallel to the Y-axis between the vibrating arm 135C and the vibrating arm 135D. Thus, mutually opposite twisting moments are generated at the central axes r1, r2, so bending vibrations occur in the vibrating portion 120. At this time, distortion concentrates in regions near the central axes r1, r2 in the base portion 130.

Processing Flow

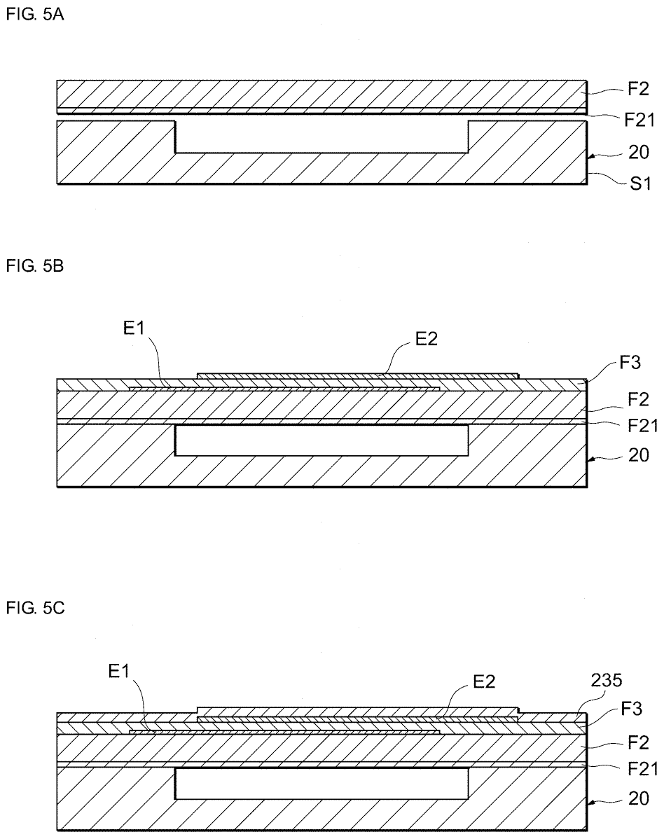

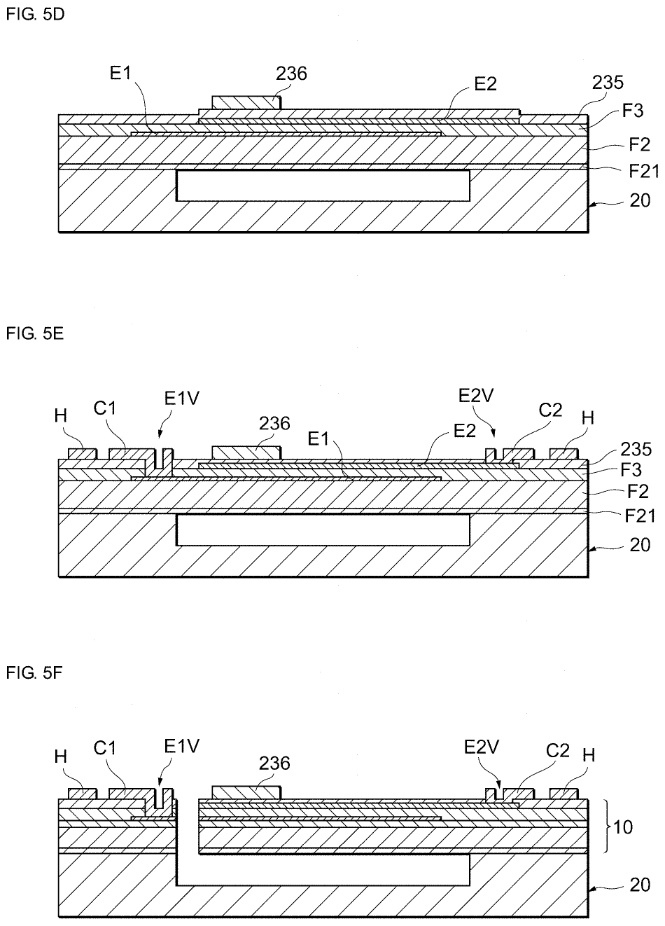

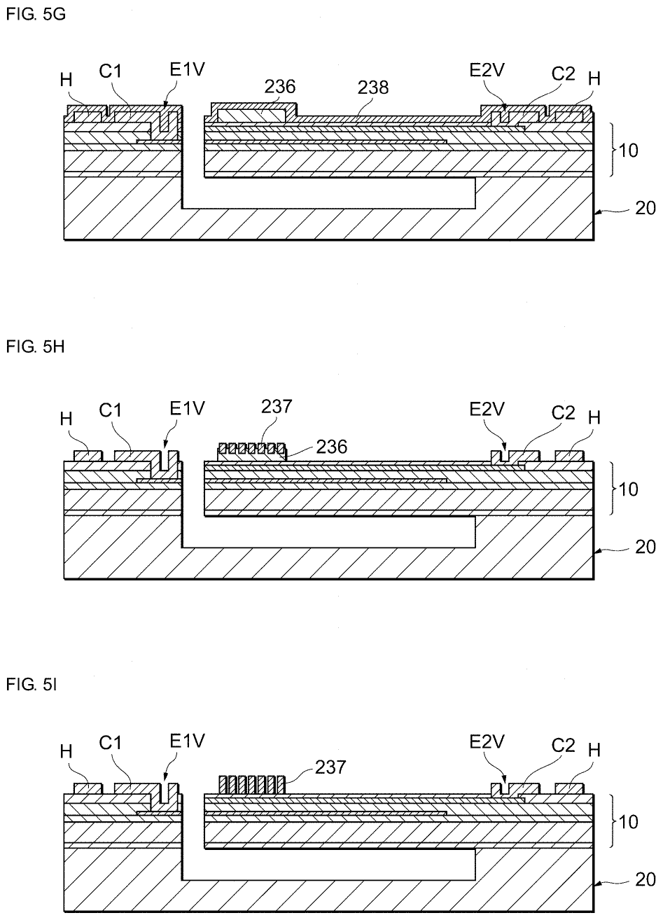

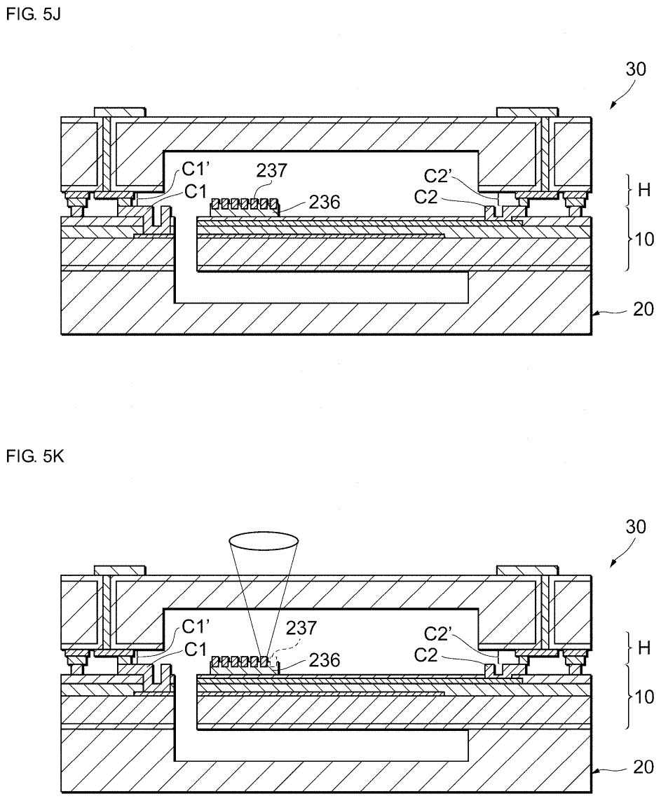

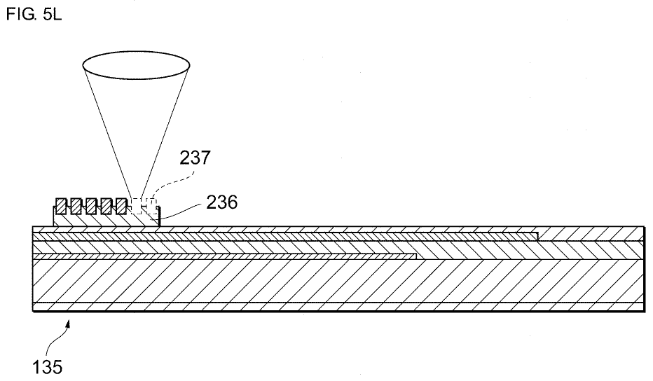

A manufacturing method for the resonant device 1 according to the present embodiment will be described with reference to FIG. 5A to FIG. 5L. In a manufacturing method for the resonator 10 according to the present embodiment, in the F adjusting step (described below), part of the plurality of adjusting films 237 is removed by irradiating laser through the top lid, with the result that the weight of each vibrating arm 135 changes. Thus, the resonant frequency of the resonator 10 is increased to adjust the resonant frequency to a desired value, and the resonant device 1 is manufactured.

FIG. 5A to FIG. 5K are views that show an example of a processing flow for the resonant device 1 according to the present embodiment. It is noted that FIG. 5A to FIG. 5K illustrate one of a plurality of resonant devices 1 to be formed in a wafer for the sake of convenience; however, the resonant device 1 is obtained as follows. As in the case of an ordinary MEMS process, a plurality of resonant devices is formed in a wafer and then the wafer is divided.

In the first step shown in FIG. 5A, a silicon oxide layer F21 is formed on a prepared Si substrate F2 by thermal oxidation. Subsequently, a bottom lid 20 having a recess 21 is prepared, the bottom lid 20 and the Si substrate F2 on which the silicon oxide layer F21 is formed are disposed such that the bottom surface of the Si substrate F2 faces the bottom lid 20, and bonded to each other at a side wall 23. Although not shown in FIG. 5A, it is desirable that the surface of the Si substrate F2 be planarized by chemical-mechanical polishing or treatment, such as etch back, after bonding.

After that, in the step shown in FIG. 5B, a lower electrode, and the like, are further formed on the surface of the Si substrate F2 by, for example, forming, patterning, and etching of a metal layer E1 to be the material of the lower electrode or wires. Subsequently, a piezoelectric thin film F3 is laminated on the surface of the metal layer E1, and an upper electrode, and the like, are further formed on the piezoelectric thin film F3 by, for example, forming, patterning, and etching of a metal layer E2 to be the material of the upper electrode or wires.

Then, in the step shown in FIG. 5C, a protective film 235 is laminated on the surface of the metal layer E2.

Subsequently, in the step shown in FIG. 5D, a metal layer made of molybdenum is laminated on the surface of the protective film 235, and the metal layer is processed by etching, or the like, with the result that a base film 236 is formed near a portion that is a free end of each vibrating arm 135 (see FIG. 5F).

After that, in the step shown in FIG. 5E, vias E1V, E2V for respectively connecting the lower electrode and the upper electrode to an external power supply are formed in the resonator 10. After the vias E1V, E2V are formed, the vias E1V, E2V are filled with metal, such as aluminum, and extended lines C1, C2 that extend the lower electrode and the upper electrode to a holding portion 140 are formed. In addition, a bonding portion H is formed on the holding portion 140.

Then, in the step shown in FIG. 5F, the protective film 235, the metal layer E2, the piezoelectric thin film F3, the metal layer E1, the piezoelectric thin film F31, the Si substrate F2, and the silicon oxide layer F21 are sequentially removed by etching, or the like, with the result that the vibrating portion 120 and the holding arms 111, 112 are formed, and the resonator 10 is formed.

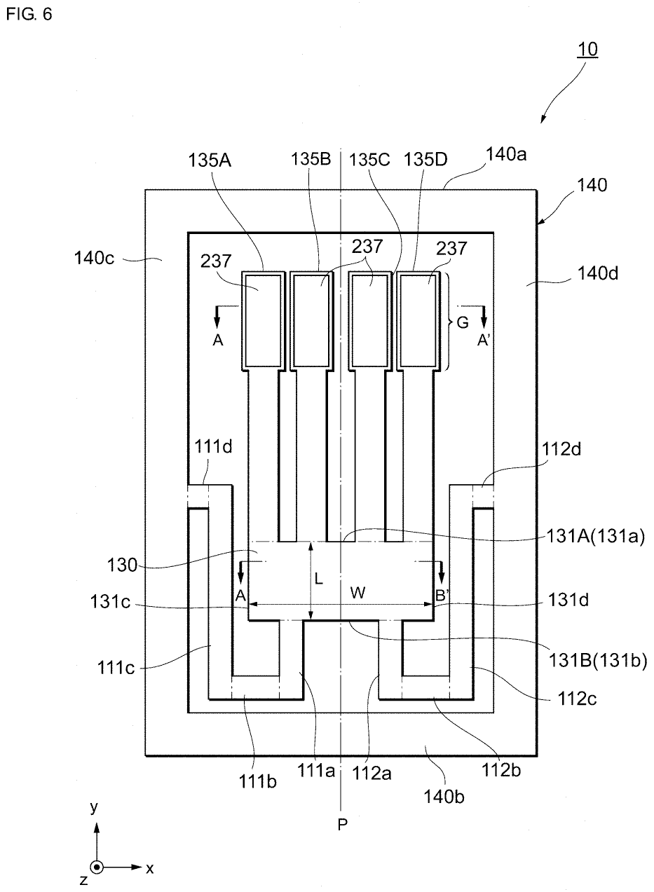

Subsequently, in the step shown in FIG. 5G, a silicon oxide film 238 is formed on the surface of the resonator 10. Then, the silicon oxide film 238 is etched into a plurality of pattern shapes whose diameter is greater than or equal to approximately 0.1 μm and less than or equal to approximately 20 μm by using, for example, photolithography. Thus, a surface other than portions to be oxidized (that is, portions where the adjusting films 237 are formed) in the resonator 10 is masked. After application of heat treatment in an oxygen atmosphere, the silicon oxide film 238 is removed. Thus, each base film 236 can be partially oxidized into a plurality of pattern shapes whose diameter is greater than or equal to approximately 0.1 μm and less than or equal to approximately 20 μm to form adjusting films 237 (FIG. 5H). Molybdenum oxide may be formed on the entire surface of an Mo film by removing a silicon oxide film on the Mo film (see FIG. 6). A wider frequency adjusting range can be obtained by removing a wide region. In oxidizing a base film, the base film may be oxidized into MoO₂ (molybdenum dioxide) or may be oxidized into MoO₃ (molybdenum trioxide). However, MoO₂ (molybdenum dioxide) does not sublime, so forming the adjusting films 237 by oxidizing the base film into MoO₂ (molybdenum dioxide) is less influenced by sealing. Molybdenum oxide is formed by oxidizing Mo. Alternatively, molybdenum may be directly formed by, for example, sputtering, or the like. It is known that a molybdenum oxide film containing MoO₂ is formed by sputtering.

The amount of oxidation in a thickness direction in each base film 236 can be adjusted with a duration or temperature for heat treatment. For example, instead of the configuration shown in FIG. 5H, the Mo layer is eliminated by oxidizing the entire base film 236 in the thickness direction into MoO₃ (FIG. 5I).

When the silicon oxide film 238 is, for example, formed and removed, a natural oxide film can be formed on the surface of each base film 236. A natural oxide film is a film sufficiently thinner than the adjusting film 237 (for example, less than or equal to 50 nm). Therefore, even when a natural oxide film is formed, frequency can be adjusted without producing a burr in the F adjusting step (described later).

Although not indispensable, after the resonator 10 is formed, a trimming step in which the film thickness of the resonator 10 is roughly adjusted may be performed according to an exemplary aspect. With the trimming step, variations in frequency can be reduced among a plurality of resonant devices 1 that are manufactured in the same wafer.

In the trimming step, first, the resonant frequency of each resonator 10 is measured, and a frequency distribution is calculated. Subsequently, the film thickness of each resonator 10 is adjusted based on the calculated frequency distribution. The film thickness of each resonator 10 is adjusted by, for example, etching through irradiation of argon (Ar) ion beam. At this time, irradiation of ion beam may be performed on the entire surface of the resonator 10 or may be performed only on the weight portion G at the distal end of each vibrating arm 135 with the use of, for example, a mask, or the like. When ion beam is irradiated to the entire surface, it is desirable that a protective film made of, for example, AlN, having a lower etching rate than Mo or molybdenum oxide be exposed in a region whose displacement is small. Thus, efficient frequency adjustment with a reduced change in temperature characteristics due to irradiation can be performed. After the film thickness of the resonator 10 is adjusted, it is desirable that the resonator 10 be cleaned to remove fly-off films. In the trimming step, other than ion beam, plasma etching, or the like, may be used. Preferably, adjustment of frequency through the trimming step is compatible with wide-range frequency adjustment as much as possible. Alternatively, frequency may be adjusted by using laser.

Subsequently, in the step shown in FIG. 5J, a step of sealing (packaging) the resonator 10 is performed. Specifically, in this step, a top lid 30 and a bottom lid 20 are disposed to face each other with the resonator 10 interposed therebetween. The top lid 30 aligned in position such that the recess 31 of the top lid 30 matches the recess 21 of the bottom lid 20 is bonded to the bottom lid 20 via the bonding portion H. Electrodes C1′, C2′ for connection with the extended lines C1, C2 are formed on the top lid 30. The electrodes C1′, C2′ are made from metal layers of, for example, aluminum, germanium, or the like. The metal layers E1, E2 are connected via the electrodes C1′, C2′ to a circuit provided outside. When the bottom lid 20 and the top lid 30 are bonded to each other, a plurality of resonant devices 1 is formed by cutting with a dicing machine.

After that, in the step shown in FIG. 5K, the F adjusting step of adjusting the resonant frequency is performed. In the F adjusting step, the resonant frequency is adjusted by cutting away the adjusting film 237 through irradiation of laser via the top lid 30. In the previous step (FIG. 5J), the resonator 10 is sealed by the top lid 30 and the bottom lid 20; however, laser can be irradiated to the adjusting films 237 by transmitting laser through the top lid 30 (or the bottom lid 20) when the frequency of laser to be used is selected. For example, when the top lid 30 is made of silicon as in the case of the present embodiment, laser having a frequency higher than or equal to 600 nm is preferably used.

FIG. 5L is a schematic diagram that schematically shows a state where some adjusting films (shown in dashed lines) are removed in the F adjusting step. In the F adjusting step, frequency can be increased by removing some adjusting films 237 at the distal end of the weight portion G can be increased. Furthermore, when laser beam is adjusted by using a lens, or the like, to set its focal point on the intended adjusting film 237, the adjusting film 237 can be efficiently removed.

In general, molybdenum oxide is lower in sublimation temperature and higher in laser absorption than molybdenum. Therefore, when molybdenum oxide is used for the adjusting films 237, only the adjusting films 237 can be removed with laser without almost any influence on the base film 236 in the F adjusting step. As a result, the base film 236 remains, so damage to the piezoelectric thin film F3 through the F adjusting step can be reduced. Advantageously, since the base film 236 remains without being cut away, characteristic variations due to a portion where the base film 236 is cut away can be prevented. Furthermore, when laser is used in the F adjusting step, generation of heat is partial and is cooled in a short time, so further accurate frequency adjustment can be performed as compared to, for example, an adjusting method that oxidizes molybdenum.

In this way, with the frequency adjusting method in the present embodiment, the F adjusting step can be performed after the resonator 10 is sealed. The frequency of the resonator 10 varies depending on heat that is generated when the resonator 10 is sealed or a vacuum state resulting from sealing. Such frequency variations resulting from sealing can be corrected by performing the F adjusting step after sealing, so further highly accurate frequency can be obtained. Since the influence of cutting with a dicing machine on frequency is small, the F adjusting step may be performed in a wafer state after sealing before cutting with a dicing machine. In addition, when the plurality of adjusting films 237 is formed in a spot shape, frequency can be adjusted by removing all the predetermined number of the adjusting films 237 among the plurality of adjusting films 237. Thus, when one adjusting film 237 is focused, a situation that only part of the adjusting film 237 remains as a burr can be reduced, so a decrease in characteristics can be prevented.

### Second Exemplary Embodiment

From a second embodiment, the description of similar matters to those of the first embodiment is omitted, and only the differences will be described. Particularly, it is noted that similar operation and advantageous effects with similar components will not be repeated one by one for each embodiment.

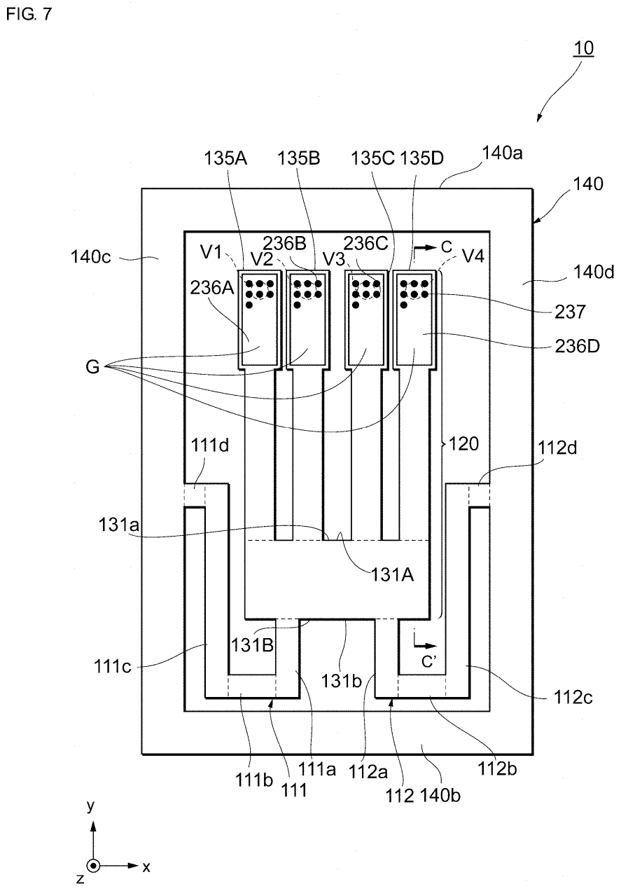

FIG. 7 is a plan view that schematically shows an example of the structure of the resonator 10 according to the present embodiment. Hereinafter, of the detailed components of the resonator 10 according to the present embodiment, differences from the first embodiment will be mainly described. The resonator 10 according to the present embodiment includes vias V1 to V4 in addition to the configuration described in the first embodiment.

The vias V1 to V4 are holes respectively formed at the distal ends (e.g., weight portions G) of the vibrating arms 135 and filled with metal, and respectively connect the base films 236 with the metal layer E1 or E2 (see FIG. 4).

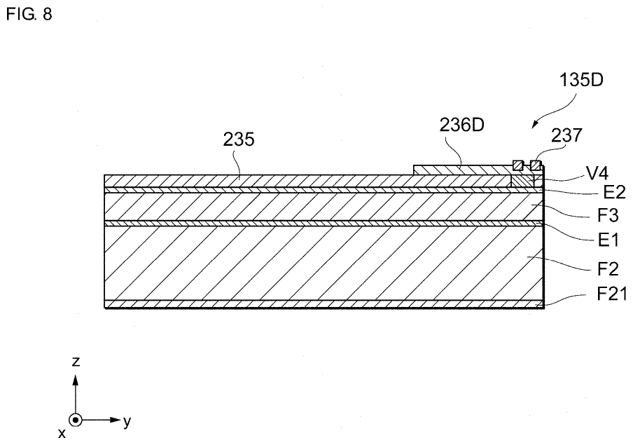

FIG. 8 is a schematic diagram that shows the cross-sectional view taken along the line C-C′ in FIG. 7. A mode of connection between each base film 236 and the metal layer E1 or E2 in the resonator 10 according to the present embodiment will be described with reference to FIG. 7 by taking the case where the base film 236 is connected to the metal layer E2 as an example.

As shown in FIG. 8, the via V4 is formed by filling an electrically conductive substance into a hole formed by removing part of the protective film 235 at the distal end of the vibrating arm 135D such that the metal layer E2 is exposed. The electrically conductive substance that places importance on the via V4 is, for example, Mo (molybdenum), aluminum (Al), or the like.

The advantageous effect resulting from electrical connection of each base film 236 with the metal layer E1 or the metal layer E2 will be described. In the F adjusting step (described later), when laser is irradiated to the resonator 10, laser is also irradiated to the protective film 235, so the protective film 235 is also electrified with the electric charge of laser. When a pyroelectric material is used for the protective film 235, a pyroelectric effect appears as a result of an increase or decrease in the temperature of heat, so electric charge precipitates on the interface of the protective film 235.

In the resonator 10 according to the present embodiment, the base films 236, each made of an electrically conductive substance and formed on part of the protective film 235, are respectively connected to the metal layer E2 or E1 via the vias V1 to V4. Thus, electric charge with which the protective film 235 is electrified can be moved to the metal layers E2, E1. Electric charge moved to the metal layers E2, E1 can be released to the outside of the resonant device 1 via connection terminals with an external device, connected to the metal layers E2, E1. In this way, with the resonator 10 according to the present embodiment, electrification of the protective film 235 formed in the vibrating portion 120 with electric charge can be reduced, so variations in resonant frequency caused by electric charge with which the vibrating portion 120 is electrified can be prevented.

In addition, when the base film 236 is connected to the metal layer E2, an electrically conductive layer (base film 236) formed on the protective film 235 can be connected to a layer near the protective film 235. Thus, the influence of electric charge with which the protective film 235 is electrified on resonant frequency can be further reduced. When the base film 236 is connected to the metal layer E2 and a piezoelectric body, such as AlN, is used for the protective film 235, a piezoelectric body having the same orientation as the piezoelectric thin film F3 is preferably used. Thus, the base film 236 can be connected to the metal layer E2 without interfering with vibrations of the vibrating arm 135.

A mode of connection, material, advantageous effect, and the like, of each of the vias V1, V2, V3 are similar to those of the via V4, so the description is omitted. The other configuration and functions of the resonator 10 are similar to those of the first embodiment.

### Third Exemplary Embodiment

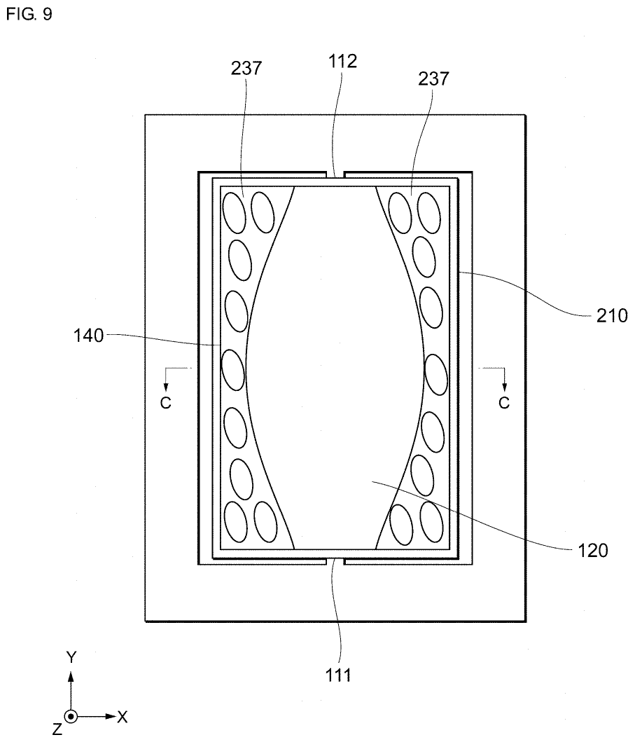

Of the detailed components of the resonator 10 according to a third embodiment, differences from the first embodiment will be mainly described with reference to FIG. 9 to FIG. 11.

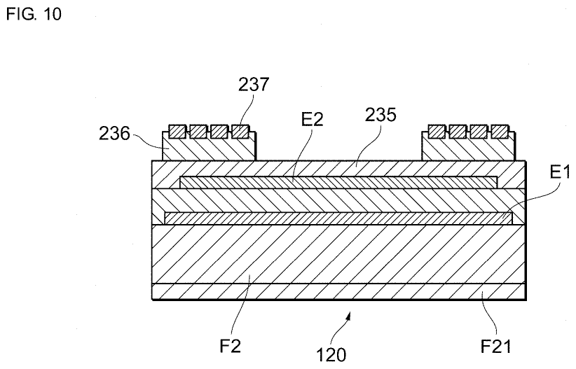

FIG. 9 is a plan view of the resonator 10 according to the present embodiment. FIG. 10 is a cross-sectional view of the resonator 10, taken along the line D-D′. In the present embodiment, the resonator 10 is an in-plane vibrator that performs contour vibrations in the XY-plane.

Vibrating Portion 120

The vibrating portion 120 has a substantially rectangular parallelepiped outline expanding in a planar shape along the XY-plane in the Cartesian coordinate system of FIG. 9. The vibrating portion 120 has short sides 121a, 121b in the X-axis direction and long sides 121c, 121d in the Y-axis direction. The vibrating portion 120 is connected to the holding portion 140 by the holding arms 111, 112 at short sides 121a, 121b and is held. The protective film 235 is formed so as to cover the entire surface of the vibrating portion 120.

The base films 236 are laminated on the surface of the protective film 235. The base films 236 are formed to cover at least four corners of the vibrating portion 120. In the present embodiment, the base films 236 each are formed over a region at one of the long sides of the vibrating portion 120 so as to connect two corner regions arranged along the long side among the four corner regions. The other configuration of the vibrating portion 120 is similar to that of the first embodiment.

(2) Holding Arms 111, 112

In the present embodiment, each of the holding arms 111, 112 has a substantially rectangular shape having long sides in the Y-axis direction and short sides in the X-axis direction.

One end of the holding arm 111 is connected near the center of the short side 121a in the vibrating portion 120, and the holding arm 111 extends substantially perpendicularly from there along the Y-axis direction. The other end of the holding arm 111 is connected near the center of a frame element 140a in the holding portion 140.

On the other hand, one end of the holding arm 112 is connected near the center of the short side 121b in the vibrating portion 120, and the holding arm 112 extends substantially perpendicularly from there along the Y-axis direction. The other end of the holding arm 112 is connected near the center of a frame element 140b in the holding portion 140. The other configurations and functions of the holding arms 111, 112 are similar to those of the first embodiment.

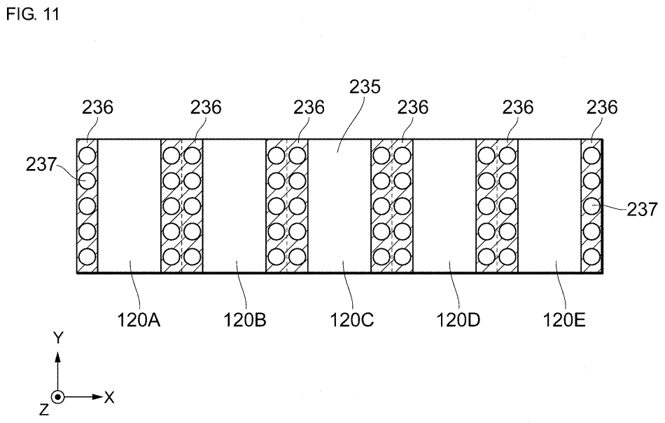

In the in-plane vibrator that performs contour vibrations as in the case of the present embodiment, when the vibrating portion 120 vibrates in harmonic mode, the vibrating portion 120 is segmented into a plurality of vibrating regions (vibrating regions 120A to 120E of FIG. 11) along a vibrating direction. FIG. 11 is a diagram that schematically shows the configuration of the vibrating portion 120 when the vibrating portion 120 vibrates in harmonic mode. In this case, as shown in FIG. 11, the base film 236 is, for example, formed along the long side of each vibrating region.

### Fourth Exemplary Embodiment

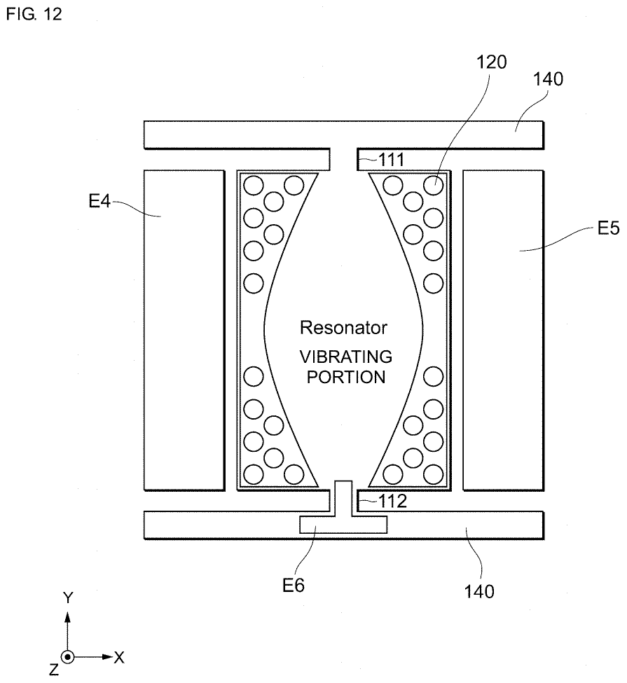

Of the detailed components of the resonator 10 according to a fourth embodiment, differences from the first embodiment will be mainly described with reference to FIG. 12. FIG. 12 is a plan view of the resonator 10 using an electrostatic MEMS technology.

In the resonator 10 according to the present embodiment, no piezoelectric body is formed in the vibrating portion 120, and the vibrating portion 120 is made of semiconductor silicon. As shown in FIG. 12, driving electrodes E4, E5 are respectively provided on opposite sides of the vibrating portion 120. A detection electrode E6 is extended from the vibrating portion 120. The detection electrode E6 is connected to an output circuit (not shown). Alternating electric fields having the same phase are respectively applied to the driving electrodes E4, E5. The vibrating portion 120 performs contour vibrations in the XY-plane shown in FIG. 12 when a voltage is applied to the driving electrodes E4, E5. At this time, in the resonator 10, a change in electrostatic capacity that is generated between the vibrating portion 120 and each of the driving electrodes E4, E5 is detected by the detection electrode E6 and is output to the output circuit via the detection electrode E6. For example, when a voltage to be applied to the driving electrodes E4, E5 is controlled according to an output electrostatic capacity, vibrations having a desired frequency is obtained in the vibrating portion 120.

On the surface of the vibrating portion 120, the base films 236 are formed to cover at least four corners of the vibrating portion 120. In the present embodiment, the base films 236 each are formed over a region at one of the long sides of the vibrating portion 120 so as to connect two corner regions arranged along the long side among the four corner regions. In the present embodiment, no protective film 235 is formed; however, it should be appreciated that the configuration is not limited thereto. The shape of the vibrating portion 120 is not limited to the one shown in FIG. 12 and may be, for example, a circular or polygonal plate shape. The other configuration, functions, and the like, are similar to those of the first embodiment.

[Additional Exemplary Embodiments]

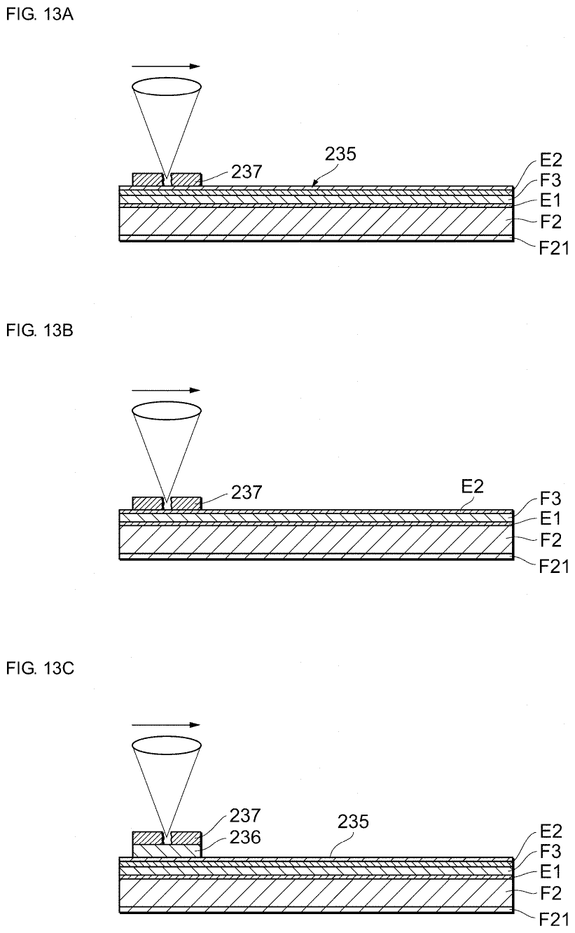

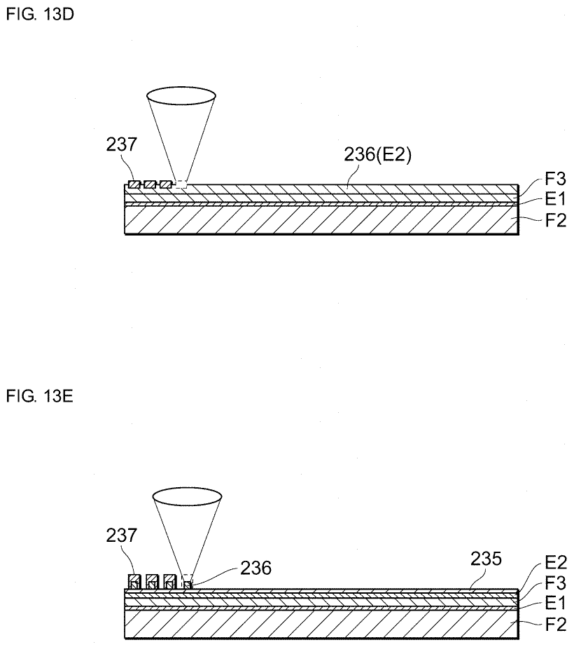

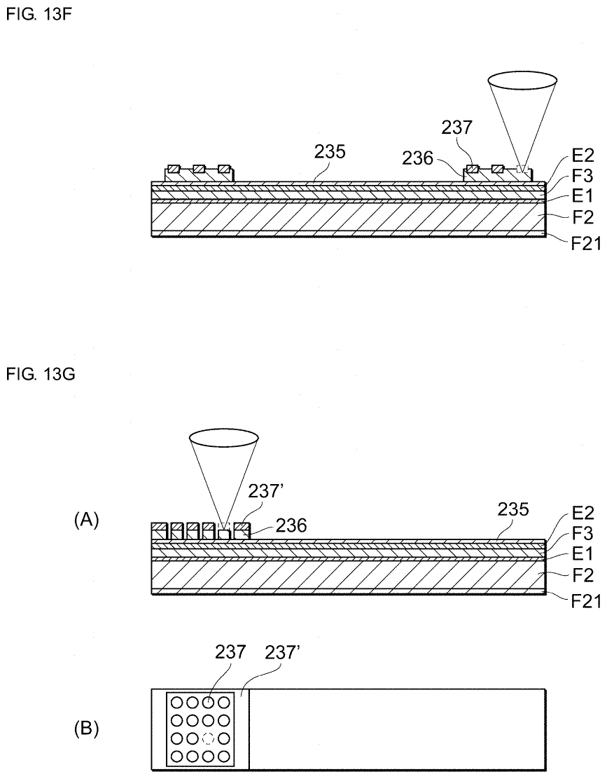

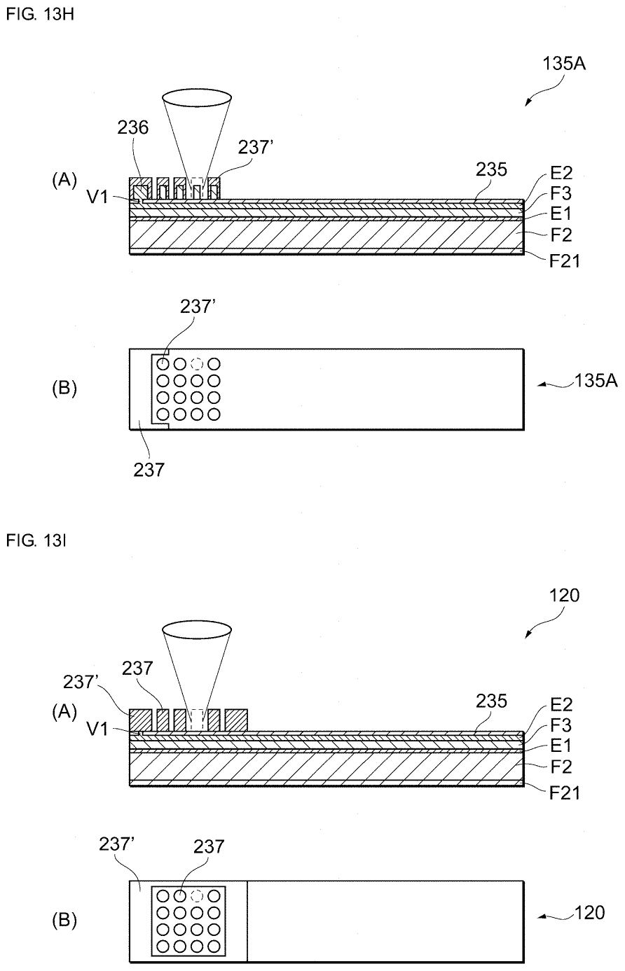

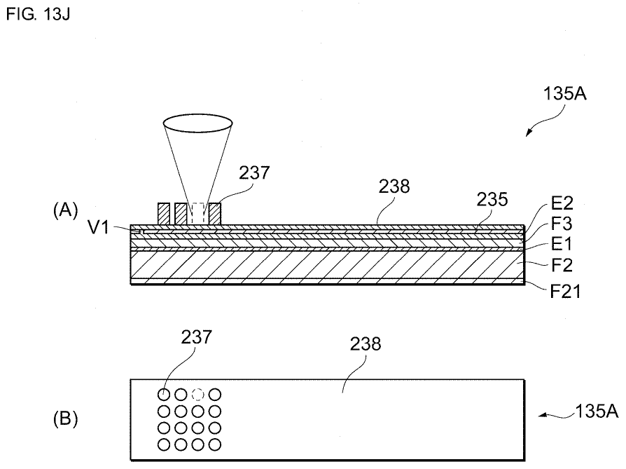

Variations of the F adjusting step or multilayer structure will be described with reference to FIG. 13A to FIG. 13I. FIG. 13A to FIG. 13I each are a schematic view that schematically shows a state where part of the adjusting film or some of the adjusting films are removed in the F adjusting step.

In the first embodiment, the example in which the silicon oxide film 238 is etched into a pattern shape in the step shown in FIG. 5G is described. In this respect, FIG. 13A, FIG. 13B, and FIG. 13C show a state where the F adjusting step is performed when the adjusting film 237 is formed on the entire surface of each base film 236 by removing the silicon oxide film 238 from the entire surface of the base film 236 (see FIG. 6). FIG. 13A and FIG. 13B are examples in which the base film 236 is entirely oxidized in the thickness direction. FIG. 13C shows an example in which the base film 236 is partially oxidized in the thickness direction. As for the multilayer structure, FIG. 13A shows the configuration in which the metal layer (i.e., upper electrode) E2 is covered with the protective film 235 as in the case of the above-described example, while FIG. 13B shows the configuration in which the metal layer E2 is exposed.

When the adjusting film 237 is formed on the entire surface of the base film 236, the adjusting film 237 can be removed over a wide range by gradually moving the irradiation position of laser, so frequency adjustment with a large rate of change in frequency can be performed. When the metal layer E2 is covered with the protective film 235 as shown in FIG. 13A, damage to the piezoelectric thin film F3 can be further reduced.

FIG. 13D to FIG. 13G show examples of the case where, in the resonator 10 having a multilayer structure different from those of the above-described embodiments, the silicon oxide film 238 is patterned and the adjusting film 237 is formed into a plurality of pattern shapes. In the example of FIG. 13D, the example in which the base film 236 also serves as the electrode layer E2 (i.e., upper electrode) is shown as a multilayer structure. When the base film 236 also serves as the electrode layer E2, a further simple multilayer structure can be achieved.

FIG. 13E shows an example in which the adjusting films 237 are formed to cover the side surfaces of the base films 236 although the multilayer structure is similar to that shown in FIG. 4. For example, in the above-described step of FIG. 5F, the base film 236 is patterned in advance, and the patterned base film 236 is oxidized, with the result that such a configuration can be obtained. In the F adjusting step of this case, the adjusting film 237 that covers the side surface of the base film 236 is also preferably removed; however, the configuration is not limited thereto. For example, only a portion covering the top surface may be removed.

FIG. 13F shows a state where the F adjusting step is performed when the base film 236 and the adjusting films 237 are also formed at the base portion (near the fixed end) of the vibrating arm 135. In this case, frequency can be increased by removing the adjusting film 237 at the weight portion G, and frequency can be decreased by removing the root-side adjusting film 237.

FIG. 13H and FIG. 13I show a state where the F adjusting step is performed when the adjusting film 237 having a pattern different from that of the above-described example is formed. In FIG. 13H, as well as FIG. 13E, the side surface of the base film 236 is also covered with the adjusting film 237. As shown in FIG. 13H and FIG. 13I, another pattern 237′ different from the adjusting film 237 is formed at least at the distal end of the weight portion G, and the other pattern 237′ is connected to the upper electrode (electrode layer E2) or the lower electrode (electrode layer E1). Thus, electric charge can be further efficiently released. Connection can be performed by, for example, forming a via (via V1 in the example of FIG. 13H) extending through the protective film 235 in the other pattern 237′. The other pattern 237′ is desirably not subjected to irradiation of laser to maintain the connection.

FIG. 13J shows an example in which no base film 236 is formed on the protective film 235, another electrically conductive film 239, such as gold, is formed, and the adjusting film 237 is formed on the electrically conductive film 239.

In general, it should be appreciated that exemplary embodiments of the present invention are described above. For example, a manufacturing method for a resonant device 1 according to an exemplary embodiment is a manufacturing method for a resonant device 1 including a resonator 10 having a vibrating portion 120 configured to vibrate according to a voltage applied to an electrode thereon. The exemplary method includes forming an adjusting film 237 made of molybdenum oxide in a region whose displacement caused by vibrations is greater than a displacement of another region in the vibrating portion 120, and adjusting a frequency of the resonator 10 by removing at least part of the adjusting film 237 with laser. With this configuration, highly accurate frequency adjustment can be performed with a further easy method.

Preferably, the forming of the adjusting film 237 includes forming the adjusting film 237 in a plurality of spot-shaped adjusting films 237, and the adjusting of the frequency removes at least one of the spot-shaped adjusting films 237. The adjusting of the frequency may further include irradiating laser having a spot diameter greater than a diameter of each of the plurality of spot-shaped adjusting films 237. In this way, with the manufacturing method for the resonant device 1 according to the embodiment of the present invention, the plurality of adjusting films 237 is formed in a spot shape. The frequency is adjusted by removing all the predetermined number of the adjusting films 237 among the plurality of adjusting films 237. Thus, when one adjusting film 237 is focused, a situation that only part of the adjusting film 237 remains as a burr can be reduced, so a decrease in characteristics can be prevented.

The above-described method may further include forming a vibrating portion 120, and the step of forming the vibrating portion 120 may include forming a first electrode layer E1, a piezoelectric layer F3, and a second electrode layer E2 sequentially on a top surface of a substrate F2. Preferably, the forming of the vibrating portion 120 includes forming a vibrating arm 135 that performs bending vibrations, from the first electrode layer E1, the second electrode layer E2, and the piezoelectric layer F3, and the region whose displacement caused by vibrations is greater than a displacement of another region is a region at a distal end of the vibrating arm 135. Preferably, the forming of the vibrating portion 120 includes forming a rectangular vibrating portion 120 that performs contour vibrations, from the first electrode layer E1, the second electrode layer E2, and the piezoelectric layer F3, and the region whose displacement caused by vibrations is greater than a displacement of another region is a region at four corners of the vibrating portion 120.

Preferably, the vibrating portion 120 has a base film 236 made of molybdenum in the region whose displacement caused by vibrations is greater than a displacement of another region, and the forming of the adjusting film 237 includes forming the adjusting film 237 by oxidizing the base film 236. Preferably, the step of forming the vibrating portion 120 further includes forming a protective film 235 on a surface of the second electrode layer E2 and forming the base film 236 on the protective film 235.

The forming of the vibrating portion 120 may further include electrically connecting the base film 236 to the first electrode layer E1 or the second electrode layer E2. The forming of the vibrating portion 120 may further include forming a protective film 235 on the second electrode layer E2, and the forming of the adjusting film 237 may further include electrically connecting the adjusting film 237 to the first electrode layer E1 or the second electrode layer E2. With this configuration, electrification of the protective film 235 formed in the vibrating portion 120 with electric charge can be reduced, so variations in resonant frequency caused by electric charge with which the vibrating portion 120 is electrified can be prevented.

The above-described method may further include preparing a bottom lid 20 and a step of disposing a top lid 30 such that the top lid 30 faces the bottom lid 20 with the resonator 10 interposed between the top lid 30 and the bottom lid 20. Preferably, the adjusting of the frequency is performed by irradiating laser to the adjusting film 237 through the top lid 30 after the step of disposing the top lid 30. According to this exemplary embodiment, the F adjusting step can be performed after sealing the resonator 10. The frequency of the resonator 10 varies depending on heat that is generated when the resonator 10 is sealed or a vacuum state resulting from sealing. Such frequency variations resulting from sealing can be corrected by performing the F adjusting step after sealing, so further highly accurate frequency can be obtained.

A resonator 10 according to an exemplary embodiment of the present invention includes a vibrating portion 120 including a piezoelectric portion configured to vibrate according to a voltage applied to an electrode, a holding portion 140 provided at least partially around the vibrating portion 120, a holding arm 111 or holding arm 112 provided between the vibrating portion 120 and the holding portion 140, one end of the holding arm 111 or holding arm 112 being connected to the vibrating portion 120, another end of the holding arm 111 or holding arm 112 being connected to the holding portion 140, and a plurality of spot-shaped adjusting films 237 made of molybdenum oxide and formed in a region whose displacement caused by vibrations is greater than a displacement of another region in the vibrating portion 120.

Preferably, the vibrating portion 120 includes a substrate F2, and a first electrode layer E1, a piezoelectric layer F3, and a second electrode layer E2, disposed on a top surface of the substrate F2. Preferably, the vibrating portion 120 has a base film made of molybdenum in the region whose displacement caused by vibrations is greater than a displacement of another region. According to this exemplary embodiment, the oscillation characteristics of the resonator 10 can be improved.

Preferably, the vibrating portion 120 further includes a protective film 235 formed on a surface of the second electrode layer E2, and the base film 236 is formed on the protective film 235. The vibrating portion 120 may further include a via that electrically connects the base film 236 to the first electrode layer E1 or the second electrode layer E2. The vibrating portion 120 may include a protective film 235 formed on a surface of the second electrode layer E2 and a via that electrically connects the adjusting film 237 to the first electrode layer E1 or the second electrode layer E2. With this configuration, electrification of the protective film 235 formed in the vibrating portion 120 with electric charge can be reduced, so variations in resonant frequency caused by electric charge with which the vibrating portion 120 is electrified can be prevented.

Preferably, the plurality of spot-shaped adjusting films 237 each has a diameter greater than or equal to 0.1 μm and less than or equal to 20 μm.

Preferably, the vibrating portion 120 includes a vibrating arm 135 having a fixed end and a free end and configured to perform bending vibrations, and a base portion 130 having a front end connected to the fixed end of the vibrating arm 135 and a rear end opposite from the front end, and the base film 236 is formed in a region at a free end-side distal end in the vibrating arm 135. Preferably, the vibrating portion 120 has a rectangular main surface and configured to perform contour vibrations in a plane along the main surface, and the base film 236 is formed in a region at four corners of the vibrating portion 120.

A resonant device 1 according to an exemplary embodiment of the present invention includes the above-described resonator 10, a top lid 30 and a bottom lid 20 provided to face each other with the resonator 10 interposed between the top lid 30 and the bottom lid 20, and an outer electrode.

The exemplary embodiments described above are intended to easily understand the present invention, and are not intended to limit interpretation of the present invention. The present invention can be modified or improved without departing from the purport of the invention, and the present invention also encompasses equivalents thereof. That is, each of the embodiments with design changes made by persons skilled in the art as needed is also included in the scope of the present invention as long as it includes the characteristics of the present invention. For example, elements of each embodiment, the disposition, materials, conditions, shapes, sizes, and the like, of the elements are not limited to the illustrated ones, and may be changed as needed. For example, in the above-described embodiments, the resonator 10 is a flexural resonator; however, the configuration is not limited thereto. The resonator 10 may be an in-plane contour resonator including a rectangular vibrating portion. In this case, the base film 236 is preferably formed at four corners of the vibrating portion 120. In the above-described embodiments, the mode in which the F adjusting step is performed after sealing is described; however, the configuration is not limited thereto. The F adjusting step may be performed before sealing. The present invention is also applicable to frequency adjustment for, for example, electrostatic MEMS other than a piezoelectric type. (width expanding mode) The embodiments are illustrative, and, of course, elements of the different embodiments may be partially replaced or combined. The present invention also encompasses these modes as long as the features of the present invention are included.

### REFERENCE SIGNS LIST

1 resonant device
10 resonator
30 top lid
140 bottom lid
140 holding portion
140a to 140d frame element
111, 112 holding arm
120 vibrating portion
130 base portion
135A to 135D vibrating arm
F2 Si substrate
F21 silicon oxide layer (temperature characteristics correction layer)
235 protective film
236 base film
237 adjusting film

1. A manufacturing method for a resonant device that includes a resonator having a vibrating portion configured to vibrate when a voltage is applied to an electrode of the resonator, the manufacturing method comprising:
forming an adjusting film of molybdenum oxide in a displacement region of the vibrating portion having a greater displacement caused by vibrations when the voltage is applied than a displacement in another region of the vibrating portion when the voltage is applied; and
adjusting a frequency of the resonator by removing at least part of the molybdenum oxide adjusting film with a laser.

2. The manufacturing method according to claim 1,
wherein the forming of the adjusting film comprises forming the adjusting film in a plurality of spot-shaped adjusting films, and
wherein the adjusting of the frequency comprises removing at least one of the spot-shaped adjusting films to adjust the frequency of the resonator.

3. The manufacturing method according to claim 2, wherein the adjusting of the frequency further comprises irradiating the adjusting film with the laser that has a spot diameter greater than a diameter of each of the plurality of spot-shaped adjusting films.

4. The manufacturing method according to claim 1, further comprising forming the vibrating portion by forming a first electrode layer, a piezoelectric layer, and a second electrode layer sequentially on a top surface of a substrate.

5. The manufacturing method according to claim 4, wherein the forming of the vibrating portion includes forming a vibrating arm configured to perform bending vibrations, from the first electrode layer, the second electrode layer, and the piezoelectric layer, such that the displacement region having a greater displacement than the other region is a region at a distal end of the vibrating arm.

6. The manufacturing method according to claim 4, wherein the forming of the vibrating portion includes forming a rectangular vibrating portion configured to perform contour vibrations, from the first electrode layer, the second electrode layer, and the piezoelectric layer, such that the displacement region having a greater displacement than the other region is a region at four corners of the vibrating portion.

7. The manufacturing method according to claim 4, wherein the vibrating portion includes a base film comprising molybdenum in the displacement region having greater displacement caused by the vibrations than the other region, and the forming of the adjusting film includes forming the adjusting film by oxidizing the base film.

8. The manufacturing method according to claim 7, wherein the forming of the vibrating portion further includes forming a protective film on a surface of the second electrode layer and forming the base film on the protective film.

9. The manufacturing method according to claim 8, wherein the forming of the vibrating portion further includes electrically connecting the base film to one of the first electrode layer or the second electrode layer.

10. The manufacturing method according to claim 4,
wherein the forming of the vibrating portion further includes forming a protective film on the second electrode layer, and
wherein the forming of the adjusting film further includes electrically connecting the adjusting film to one of the first electrode layer or the second electrode layer.

11. The manufacturing method according to claim 1, further comprising:
preparing a bottom lid; and
disposing a top lid to face the bottom lid with the resonator interposed between the top lid and the bottom lid,
wherein the adjusting of the frequency comprises irradiating the laser to the adjusting film through the top lid after the top lid is disposed on the bottom lid.

12. A resonator comprising:
a vibrating portion configured to vibrate when a voltage is applied to an electrode of the resonator;
a frame that at least partially surrounds the vibrating portion;
at least one holding arm disposed between the vibrating portion and the frame with a first end connected to the vibrating portion and a second end connected to the frame; and
a plurality of spot-shaped adjusting films comprising molybdenum oxide and disposed in a displacement region of the vibrating portion having a greater displacement caused by vibrations when the voltage is applied to the electrode than a displacement of another region of the vibrating portion.

13. The resonator according to claim 12, wherein the vibrating portion includes a substrate, and a first electrode layer, a piezoelectric layer, and a second electrode layer, disposed on a top surface of the substrate.

14. The resonator according to claim 13, wherein the vibrating portion includes a base film comprising molybdenum in the displacement region having a greater displacement caused then by vibrations than the other region.

15. The resonator according to claim 13, wherein the vibrating portion further includes a protective film disposed on a surface of the second electrode layer, and the base film is disposed on the protective film.

16. The resonator according to claim 15, wherein the vibrating portion includes a via that electrically connects the base film to one of the first electrode layer or the second electrode layer.

17. The resonator according to claim 13, wherein the vibrating portion includes a protective film disposed on a surface of the second electrode layer, and a via that electrically connects the adjusting film to one of the first electrode layer or the second electrode layer.

18. The resonator according to claim 12, wherein the plurality of spot-shaped adjusting films each has a diameter greater than or equal to 0.1 μm and less than or equal to 20 μm.

19. The resonator according to claim 12,
wherein the vibrating portion includes a vibrating arm having a fixed end and a free end and that is configured to perform bending vibrations, and a base having a front end connected to the fixed end of the vibrating arm and a rear end opposite from the front end, and
wherein the displacement region having a greater displacement caused by the vibrations is a region at a free end-side distal end in the vibrating arm.

20. The resonator according to claim 12, wherein the vibrating portion has a rectangular main surface and is configured to perform contour vibrations in a plane along the main surface, and the displacement having greater displacement caused by the vibrations is a region at four corners of the vibrating portion.
